(19) United States
(12) Patent Application Publication
(10) Pub. No.: US 2025/0366171 A1
(43) Pub. Date: Nov. 27, 2025

(54) SEMICONDUCTOR DEVICE

(71) Applicant: ROHM CO., LTD., Kyoto (JP)

(72) Inventor: Shota IZUMI, Kyoto (JP)

(73) Assignee: ROHM CO., LTD., Kyoto (JP)

(21) Appl. No.: 19/208,991

(22) Filed: May 15, 2025

(30) Foreign Application Priority Data
May 23, 2024 (JP) 2024-083991

(51) Int. Cl. H10D 84/80; H10D 1/00; H10D 1/68; H10D 30/65; H10D 62/10; H10D 62/60; H10D 84/00

(52) U.S. Cl. CPC H10D 84/813; H10D 1/692; H10D 30/655; H10D 62/126; H10D 62/60; H10D 84/212; H10D 1/041

(57) ABSTRACT

A semiconductor device includes a main conductive region, a first conductive region, a second conductive region, a first first-side dielectric layer (first inner dielectric layer), a second first-side dielectric layer (second inner dielectric layer), a first second-side dielectric layer (first outer dielectric layer), and a second second-side dielectric layer (second outer dielectric layer). A main trench extends from the surface of an epitaxial semiconductor layer to penetrate a base epitaxial semiconductor layer and the main conductive region is electrically connected to a semiconductor substrate. A first trench and a second trench respectively extend from the surface of the epitaxial semiconductor layer to reach the base epitaxial semiconductor layer, and the first conductive region and the second conductive region are electrically insulated from the base epitaxial semiconductor layer.

### CROSS REFERENCE TO RELATED APPLICATION

This application is based upon and claims the benefit of priority of the prior Japanese Patent Application No. 2024-083991, filed on May 23, 2024, the entire contents of which are incorporated herein by reference.

### TECHNICAL FIELD

The present disclosure relates to a semiconductor device.

### BACKGROUND ART

International Publication No. WO2022/153693 discloses a semiconductor device including the deep-trench isolation (DTI) structure.

### BRIEF DESCRIPTION OF THE DRAWINGS

FIG. 1 is a plan view of a semiconductor chip.

FIG. 2 is a plan view of a device region of Embodiment 1.

FIG. 3 is a plan view of a device region of Embodiment 2.

FIG. 4A is a cross-sectional view along the arrow A-A, and FIG. 4B is a circuit diagram of the device region of FIG. 2.

FIG. 5 is a diagram showing a vertical cross-sectional structure of a semiconductor device for explaining the manufacturing method of the semiconductor device.

FIG. 6 is a diagram showing a vertical cross-sectional structure of a semiconductor device for explaining the manufacturing method of the semiconductor device.

FIG. 7 is a diagram showing a vertical cross-sectional structure of a semiconductor device for explaining the manufacturing method of the semiconductor device.

FIG. 8 is a diagram showing a vertical cross-sectional structure of a semiconductor device for explaining the manufacturing method of the semiconductor device.

FIG. 9 is a diagram showing a vertical cross-sectional structure of a semiconductor device for explaining the manufacturing method of the semiconductor device.

FIG. 10 is a diagram showing a vertical cross-sectional structure of a semiconductor device for explaining the manufacturing method of the semiconductor device.

FIG. 11 is a diagram showing a vertical cross-sectional structure of a semiconductor device for explaining the manufacturing method of the semiconductor device.

FIG. 12 is a diagram showing a vertical cross-sectional structure of a semiconductor device for explaining the manufacturing method of the semiconductor device.

FIG. 13 is a diagram showing a vertical cross-sectional structure of a semiconductor device for explaining the manufacturing method of the semiconductor device.

FIG. 14 is a diagram showing a vertical cross-sectional structure of one exemplar device.

### DETAILED DESCRIPTION OF EMBODIMENTS

Various illustrative embodiments will be described in detail below with reference to the figures. In each drawing, the same or similar components are given the same character and the descriptions thereof will not be repeated.

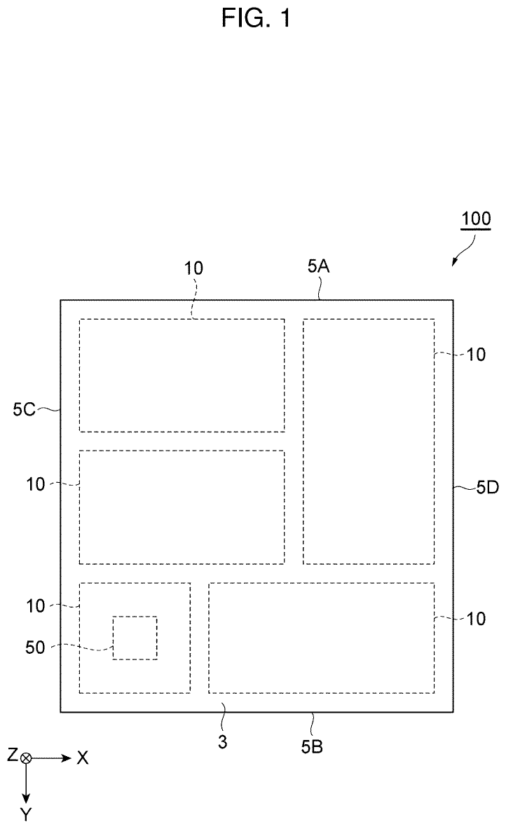

FIG. 1 is a plan view of a semiconductor chip.

A semiconductor chip 100 (semiconductor device) has a square shape. The semiconductor chip 100 includes a first primary surface 3 on one side. The surface on the opposite side from the first primary surface 3 is a rear surface. The semiconductor chip 100 also has a first side face 5A, a second side face 5B, a third side face 5C, and a fourth side face 5D that connect the first primary surface 3 to the rear surface. The thickness direction of the semiconductor chip 100 is the z-axis direction, the direction perpendicular to the z-axis direction is the x-axis direction, and the direction perpendicular to both the z-axis direction and x-axis direction is the y-axis direction. The depth direction of the semiconductor chip 100 is the positive direction of the z-axis, and the negative direction of the z-axis direction is the direction going from the rear surface of the semiconductor substrate toward the first primary surface 3 (top surface).

The first primary surface 3 and the rear surface are perpendicular to the z-axis respectively. The plan view shape (shape in a plan view) of the first primary surface 3 is a rectangle (quadrilateral) when viewed from the normal direction (z-axis direction). The plan view shape of the rear surface of the semiconductor substrate is a rectangle (quadrilateral). In a plan view, the first side face 5A and the second side face 5B that constitute two opposing sides of the rectangle extend in the x-axis direction, respectively. In a plan view, the third side face 5C and the fourth side face 5D that constitute the other two opposing sides of the rectangle extend in the y-axis direction, respectively. The respective adjacent side faces are perpendicular to each other, but they may alternatively intersect with each other at an angle other than a right angle.

The semiconductor chip 100 includes a plurality of device regions 10 disposed on the first primary surface 3. There is a gap between each device region 10 and each side face (the first side face 5A to the fourth side face 5D) of the semiconductor chip 100. The device regions 10 can take any number, any arrangement and any shape, and are not limited to specific numbers, arrangements or shapes.

In each device region 10, various types of devices are formed. In this embodiment, at least one device region 10 includes a device 50.

The device 50 is a field-effect transistor, for example. Examples of the field-effect transistor in this embodiment include a MISFET (metal insulator semiconductor field effect transistor). For the MISFET, a MOSFET (metal oxide semiconductor field effect transistor) may be used. The MOSFET in this embodiment is an ED (extended drain) MOSFET. A typical ED-MOSFET has, near the drain region, an N-type well region through which N-type carriers drift. Field-effect transistors may also be used for power transistors. The drain-to-source voltages of MISFETs are known to be HV (high voltage: between 100V and 1000V, for example), MV (middle voltage: between 30V and 100V, for example) and LV (low voltage: between 1V and 30V, for example).

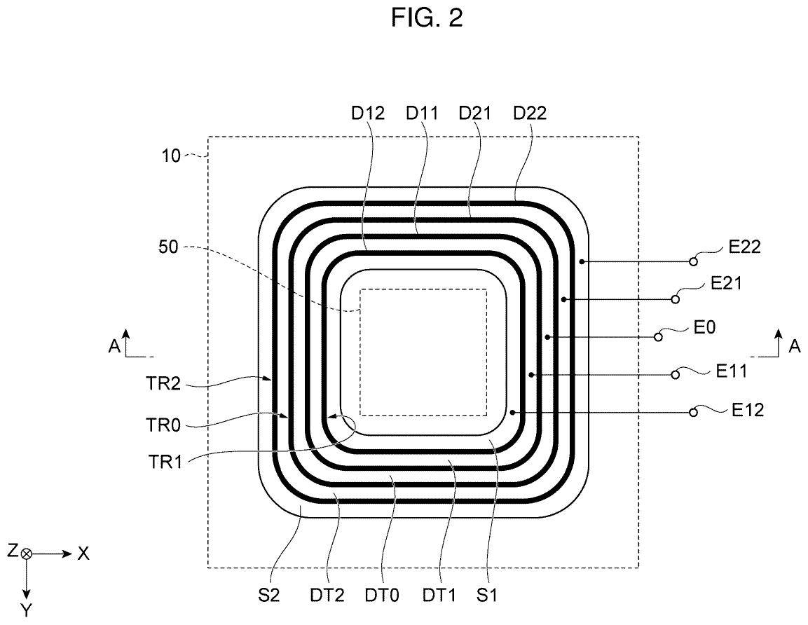

FIG. 2 is a plan view of the device region of Embodiment 1.

In the device region 10, a device 50 is disposed. In FIG. 2, an insulating region formed on the substrate surface is not shown. The device 50 is surrounded by a plurality of ring-shaped trenches formed therearound. In a ring-shaped main trench TR0, a main conductive region DT0 is embedded. In a ring-shaped first trench TR1 located on the inside of the main trench TR0, a first conductive region DT1 is embedded. In a ring-shaped second trench TR2 located on the outside of the main trench TR0, a second conductive region DT2 is embedded.

On the inside of the ring-shaped first trench TR1, a first sinker region S1 is formed. On the outside of the ring-shaped second trench TR2, a second sinker region S2 is formed.

A first inner dielectric layer D11 is formed between the main conductive region DT0 and the first conductive region DT1. A second inner dielectric layer D12 is formed between the first conductive region DT1 and the first sinker region S1. A first outer dielectric layer D21 is formed between the main conductive region DT0 and the second conductive region. A second outer dielectric layer D22 is formed between the second conductive region DT2 and the second sinker region S2.

A main electrode E0 is electrically connected to the main conductive region DT0. A first electrode E11 is electrically connected to the first conductive region DT1. A second electrode E21 is electrically connected to the second conductive region DT2. A first sinker electrode E12 is electrically connected to the first sinker region S1. A second sinker electrode E22 is electrically connected to the second sinker region S2.

In this embodiment, the first trench TR1 surrounds the device 50 in a plan view. The second trench TR2 surrounds the main trench TR0 in a plan view. In the region on the substrate surface, the region on the inside of the trenches where the device 50 is disposed and the region on the outside of the trenches are electrically isolated. Having the plurality of trenches increases this isolation effect.

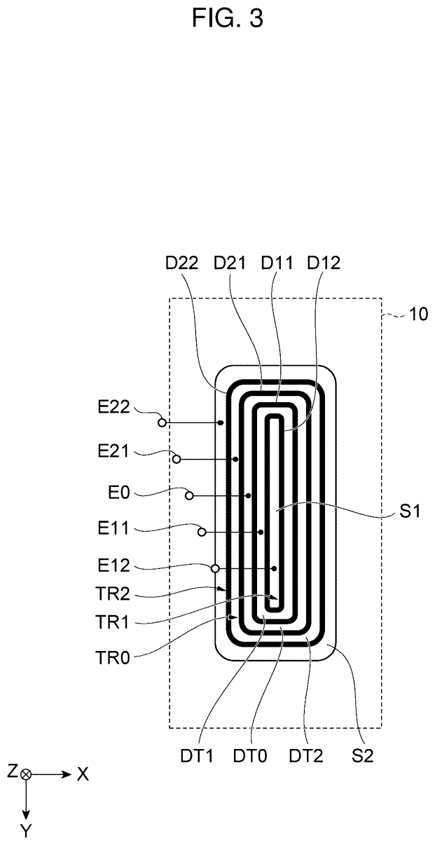

FIG. 3 is a plan view of the device region of Embodiment 2.

In FIG. 3, an insulating region formed on the substrate surface is not shown. The device region 10 of Embodiment 2 differs from the device region of Embodiment 1 in that no devices such as active elements are formed on the inside of the ring-shaped trenches, and a space region on the inside of the ring-shaped trenches extends along the y-axis. Other configurations of the device region 10 of Embodiment 2 are the same as those of the device region of Embodiment 1. In other words, the device region of Embodiment 2 does not include any active elements, and the only device included is a capacitor constituted of the ring-shaped trenches.

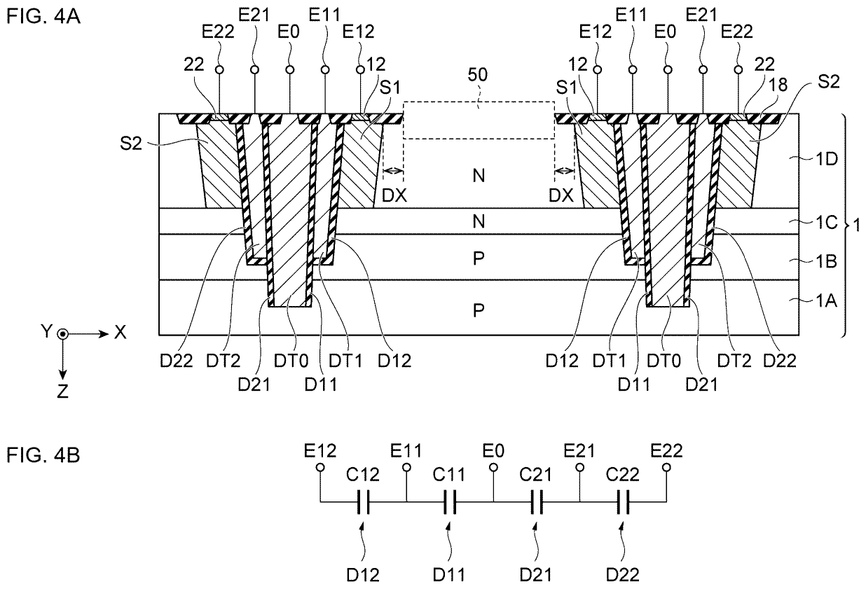

FIG. 4A is a cross-sectional view along the arrow A-A, and FIG. 4B is a circuit diagram of the device region of FIG. 2.

The semiconductor device in the device region includes a substrate 1. The substrate 1 includes a semiconductor substrate 1A, a base epitaxial semiconductor layer 1B formed on the semiconductor substrate 1A, an embedded semiconductor layer 1C formed on the base epitaxial semiconductor layer 1B, and an epitaxial semiconductor layer 1D formed on the embedded semiconductor layer 1C.

In this embodiment, the respective semiconductor regions in the device region are configured such that P-type is the first conductivity type and N-type is the second conductivity type, but these conductivity types may be switched. Examples of P-type impurity (trivalent atom) include boron (B). Examples of N-type impurity (pentavalent atom) include phosphorus (P) and arsenic (As). Each semiconductor region is made of Si (silicon), for example, but other semiconductor materials may alternatively be used.

The conductivity type of the semiconductor substrate 1A is P-type. The conductivity type of the base epitaxial semiconductor layer 1B is P-type. The conductivity type of the embedded semiconductor layer 1C is N-type. The conductivity type of the epitaxial semiconductor layer 1D is N-type. The impurity concentration of the epitaxial semiconductor layer 1D is set to be lower than the impurity concentration of the embedded semiconductor layer 1C. Between the base epitaxial semiconductor layer 1B and the embedded semiconductor layer 1C, PN junction is formed. Because the impurity concentration of the embedded semiconductor layer 1C can be set to be relatively high, the embedded semiconductor layer 1C can have a higher field intensity. In the epitaxial semiconductor layer 1D, a device 50 that can operate at a high voltage may be formed.

The device 50 is formed in the epitaxial semiconductor layer 1D.

In the epitaxial semiconductor layer 1D, the first sinker region S1 is formed. The first sinker region S1 surrounds the device 50 in a plan view. The conductivity type of the first sinker region S1 is P-type, but it may be N-type instead. On the surface of the first sinker region S1, a first sinker region contact region 12 is formed, and the surface of the first sinker region contact region 12 is connected to the first sinker electrode E12. The conductivity type of the first sinker region contact region 12 may be the same as the conductivity type of the first sinker region S1. The impurity concentration of the first sinker region contact region 12 is set to be higher than the impurity concentration of the first sinker region S1.

The first conductive region DT1 extends from the surface of the epitaxial semiconductor layer 1D to reach the base epitaxial semiconductor layer 1B. The first conductive region DT1 is made of P-type impurity-added polysilicon and the like. The first conductive region DT1 surrounds the first sinker region S1 in a plan view. The surface of the first conductive region DT1 is connected to the first electrode E11. The first conductive region DT1 is insulated from the adjacent semiconductor layers (base epitaxial semiconductor layer 1B, embedded semiconductor layer 1C, first sinker region S1) by the second inner dielectric layer D12.

The main conductive region DT0 extends from the surface of the epitaxial semiconductor layer 1D to reach into the semiconductor substrate 1A. The main conductive region DT0 is made of P-type impurity-added polysilicon and the like. The main conductive region DT0 surrounds the first conductive region DT1 in a plan view. The surface of the main conductive region DT0 is electrically connected to the main electrode E0. The main conductive region DT0 is electrically connected to the semiconductor substrate 1A.

The second conductive region DT2 extends from the surface of the epitaxial semiconductor layer 1D to reach the base epitaxial semiconductor layer 1B. The second conductive region DT2 is made of P-type impurity-added polysilicon and the like. The second conductive region DT2 surrounds the main conductive region DT0 in a plan view. The surface of the second conductive region DT2 is connected to the second electrode E21. The second conductive region DT2 is insulated from the adjacent semiconductor layers (base epitaxial semiconductor layer 1B, embedded semiconductor layer 1C, second sinker region S2) by the second outer dielectric layer D22.

In the epitaxial semiconductor layer 1D, the second sinker region S2 is formed. The second sinker region S2 surrounds the second conductive region DT2 in a plan view. The conductivity type of the second sinker region S2 is P-type, but it may be N-type instead. On the surface of the second sinker region S2, a second sinker region contact region 22 is formed, and the surface of the second sinker region contact region 22 is connected to the second sinker electrode E22. The conductivity type of the second sinker region contact region 22 may be the same as the conductivity type of the second sinker region S2. The impurity concentration of the second sinker region contact region 22 is set to be higher than the impurity concentration of the second sinker region S2.

The surface of the epitaxial semiconductor layer 1D is covered by an insulating region 18. The part where the insulating region 18 is formed may constitute STI (shallow trench isolation). The insulating region 18 is formed of an insulator such as SiO₂, for example. The insulating region 18 may be a field oxide film.

The first inner dielectric layer D11 is made of an insulator such as SiO₂, and extends from the lower surface of the insulating region 18 to reach the semiconductor substrate 1A. The second inner dielectric layer D12 is made of an insulator such as SiO₂, and extends from the lower surface of the insulating region 18 to reach the base epitaxial semiconductor layer 1B, and is connected to the first inner dielectric layer D11. The first outer dielectric layer D21 is made of an insulator such as SiO₂, and extends from the lower surface of the insulating region 18 to reach the semiconductor substrate 1A. The second outer dielectric layer D22 is made of an insulator such as SiO₂, extends from the lower surface of the insulating region 18 to reach the base epitaxial semiconductor layer 1B, and is connected to the first outer dielectric layer D21.

The conductivity type of the first sinker region S1 is P-type, and the conductivity type of the second sinker region S2 is P-type. The conductivity type of the sinker region may be N-type, but because the conductivity type of the conductive regions (DT0, DT1, DT2: P-type impurity-added polysilicon) inside the trenches is P-type, by having the same conductivity type, the waveform based on the capacitance can be improved compared with N-type. Also, when the conductivity type of the sinker region is P-type, PN junction is formed between the sinker region and the epitaxial semiconductor layer 1D, which electrically separates the sinker region from the epitaxial semiconductor layer.

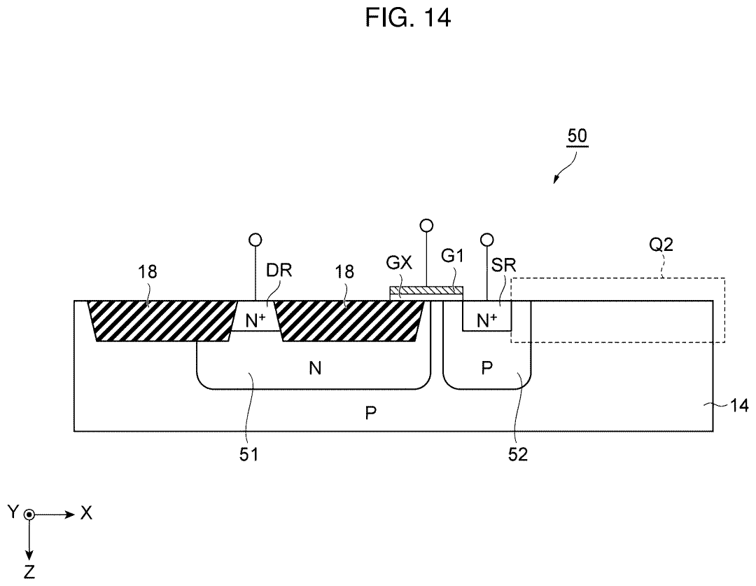

The semiconductor device of Embodiment 1 has the device 50 formed in the epitaxial semiconductor layer 1D, and in a plan view, the ring-shaped main trench is surrounding the device 50. The device 50, for example, includes a field-effect transistor formed in the semiconductor well region 14 (see FIG. 14) made of a P-type semiconductor, and the shortest distance DX between the semiconductor well region 14 (device 50) and the first sinker region S1 fulfills the following relationship:

$$2 μm ≦ D X ≦ 10 μm .$$

Next, the circuit diagram of FIG. 4B will be explained. The structure of FIG. 4A includes four capacitors (C12, C11, C21 and C22) as illustrated in FIG. 4B.

The first inner capacitor C11 is constituted of the main conductive region DT0, the first conductive region DT1, and the first inner dielectric layer D11 located between the main conductive region DT0 and the first conductive region DT1.

The second inner capacitor C12 is constituted of the first conductive region DT1, the first sinker region S1, and the second inner dielectric layer D12 located between the first conductive region DT1 and the first sinker region S1.

The first outer capacitor C21 is constituted of the main conductive region DT0, the second conductive region DT2, and the first outer dielectric layer D21 between the main conductive region DT0 and the second conductive region DT2.

The second outer capacitor C22 has a second conductive region DT2, a second sinker region S2, and a second outer dielectric layer D22 between the second conductive region DT2 and the second sinker region S2.

The second inner capacitor C12, the first inner capacitor C11, the first outer capacitor C21, and the second outer capacitor C22 are electrically connected to each other in series. By selecting two electrodes from a group of electrodes of the respective capacitors, a capacitor that has the capacitance between those selected electrodes can be achieved. In a common use case, the main electrode E0 is used for a substrate terminal, and only the second inner capacitor C12 and the second outer capacitor C22 are used for the capacitors, but use cases are not limited to this.

Next, a method for manufacturing the semiconductor device illustrated in FIGS. 4A and 4B will be explained.

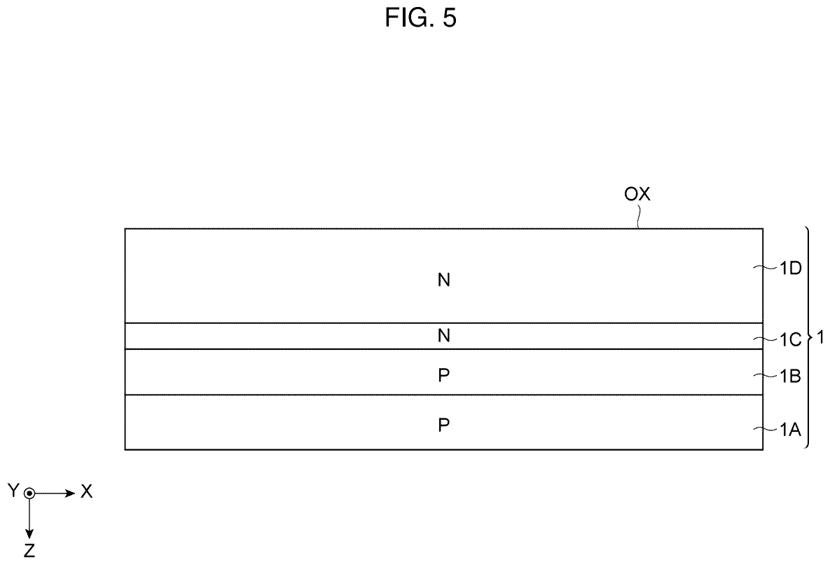

FIG. 5 is a diagram showing a vertical cross-sectional structure of a semiconductor device for explaining the manufacturing method of the semiconductor device.

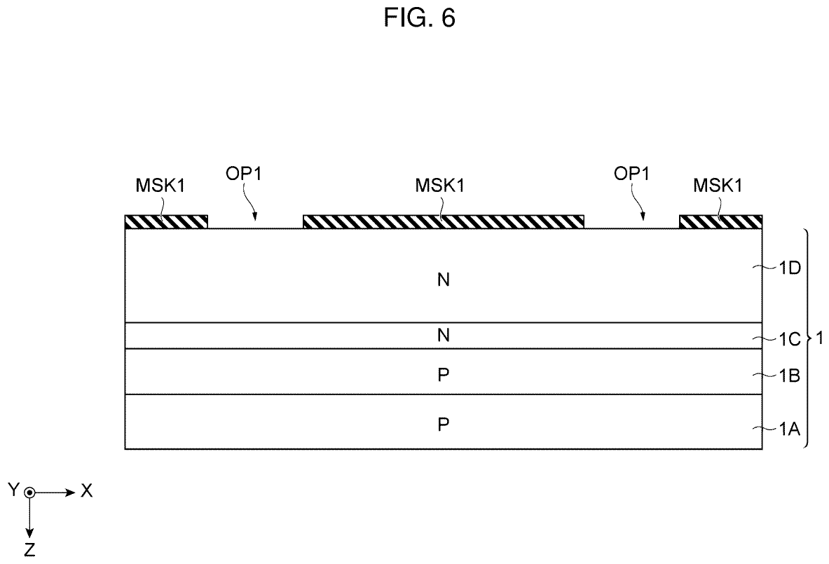

First, the base epitaxial semiconductor layer 1B is formed on the semiconductor substrate 1A. Next, the embedded semiconductor layer 1C is formed on the base epitaxial semiconductor layer 1B. Thereafter, the epitaxial semiconductor layer 1D is formed on the embedded semiconductor layer 1C. Each semiconductor layer may be formed by supplying gas that includes the material (such as Si) and impurity to the exposed surface of the substrate. To add impurity, the ion injection method or diffusion method may also be used. For example, the embedded semiconductor layer 1C may be formed by the ion injection method. On the surface of the epitaxial semiconductor layer 1D, an oxide film OX is formed. The oxide film OX is a naturally oxidated film, or oxide film that is intentionally formed, and may be present on the surface of the epitaxial semiconductor layer 1D in the subsequent steps (FIGS. 6 to 13). That is, the oxide film OX may or may not be formed on the epitaxial semiconductor layer 1D. Examples of the method for forming the epitaxial layer include the CVD method using silicon gas such as silane (SiH₄).

FIG. 6 is a diagram showing a vertical cross-sectional structure of a semiconductor device for explaining the manufacturing method of the semiconductor device.

Next, a first mask layer MSK1 is formed on the surface of the epitaxial semiconductor layer 1D. The first mask layer MSK1 is formed by, first, applying a resist to the surface of the epitaxial semiconductor layer 1D, performing exposure after setting a ring-shaped non-hardened area in a plan view, and then developing the resist. This removes the resist from the non-hardened area, resulting in the first mask layer MSK1 where, in a plan view, ring-shaped first openings OP1 are patterned.

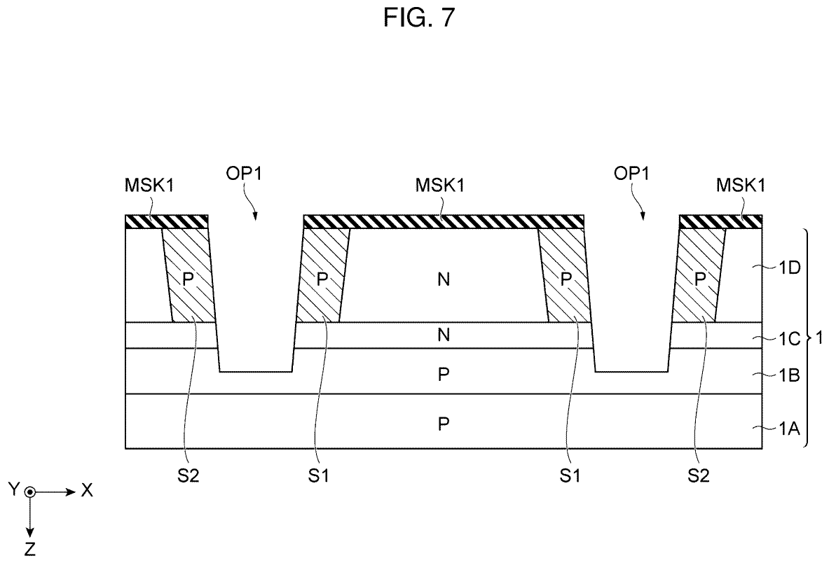

FIG. 7 is a diagram showing a vertical cross-sectional structure of a semiconductor device for explaining the manufacturing method of the semiconductor device.

Next, through the first openings OP1 of the first mask layer MSK1, etching is performed on the substrate 1 to form trenches. This etching is performed from the surface of the epitaxial semiconductor layer 1D to reach into the base epitaxial semiconductor layer 1B through the embedded semiconductor layer 1C. Because of the high aspect ratio of the trenches, anisotropic etching may be used. Examples of the anisotropic etching (dry etching) method includes RIE (reactive ion etching). Examples of the etching gas include gases containing fluorocarbons and halogens such as SF₆, but are not limited to these.

Next, the first sinker region S1 and the second sinker region S2 are formed by the ion injection method. Because the conductivity type of the first sinker region S1 and the second sinker region S2 is P-type, P-type impurity is injected into the inner surface of the trenches. Examples of the P-type impurity include boron (B). The conductivity type of the first sinker region S1 and the second sinker region S2 may be N-type instead. In the ion injection, the ion travelling direction is angled with respect to the depth direction (z-axis) of the substrate 1. After the Nth ion injection is completed, the substrate 1 is rotated around the ion travelling direction, for example, and then the N+1th ion injection is performed (N is a natural number). For example, the substrate 1 is rotated three times from the initial position, 90 degrees at a time, and undergoes the ion injection four times. The rotation angle and rotation times are not limited to those.

With the ion injection of a P-type impurity, the P-type impurity is added to areas near the trench inner surfaces of the epitaxial semiconductor layer 1D, creating the first sinker region S1 and the second sinker region S2. The P-type impurity is also added to the inner surfaces of the embedded semiconductor layer 1C and the base epitaxial semiconductor layer 1B near the trench inner surfaces. However, because the N-type impurity concentration of the embedded semiconductor layer 1C is higher than the P-type impurity concentration of the sinker region, and the conductivity type of the base epitaxial semiconductor layer 1B is P-type even before the impurity is added, the impurity state does not significantly change in those regions. When P-type impurity is injected into the high-concentration embedded semiconductor layer 1C and the bordering areas with adjacent layers, the field effect mitigation effect is expected to be achieved. After completing the ion injection, the first mask layer MSK1 may be peeled and removed. The first mask layer MSK1 may alternatively be peeled before the ion injection.

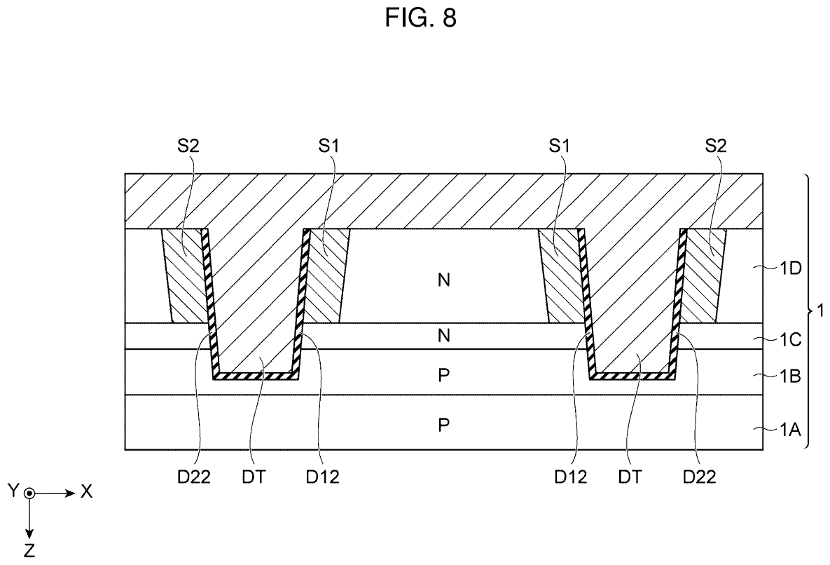

FIG. 8 is a diagram showing a vertical cross-sectional structure of a semiconductor device for explaining the manufacturing method of the semiconductor device.

Next, an insulating film is formed on the surface of the substrate 1, creating the second inner dielectric layer D12 and the second outer dielectric layer D22 made of this insulating layer in the trenches. If the insulating film is an oxide film (SiO₂), this oxide film may be formed by performing thermal oxidation on silicon, the CVD method, or sputtering. Examples of the material used in the CVD method include TEOS ((Si(OC₂H₅)₄): tetraethyl orthosilicate). After forming the insulating film on the surface of the substrate 1, the insulating film may be removed from the substate surface area except for the trench inner surfaces as needed through CMP and the like. The insulating film may be left instead of being removed. The material of the dielectric layers may be other materials than SiO₂.

After forming the second inner dielectric layer D12 and the second outer dielectric layer D22, a conductive material DT is deposited to fill up the trenches. The conductive material DT is also deposited on the surface of the epitaxial semiconductor layer 1D. The conductive material DT is a polysilicon added with P-type impurity. Examples of the deposition method include sputtering and the CVD method using a gas containing Si such as Silane.

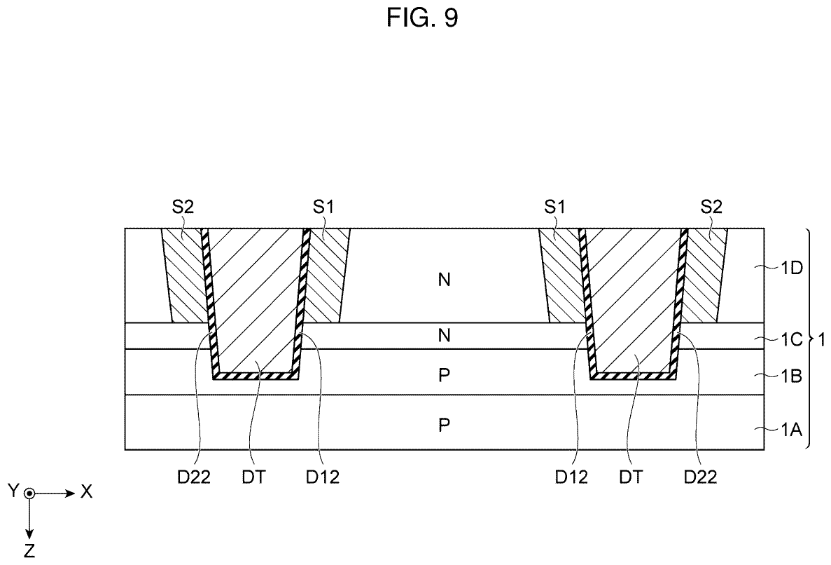

FIG. 9 is a diagram showing a vertical cross-sectional structure of a semiconductor device for explaining the manufacturing method of the semiconductor device.

Next, part of the conductive material DT on the surface of the substrate 1 is removed by CMP or the like. This exposes the top part of the second inner dielectric layer D12, the top part of the second outer dielectric layer D22, the top part of the first sinker region S1, and the top part of the second sinker region S2.

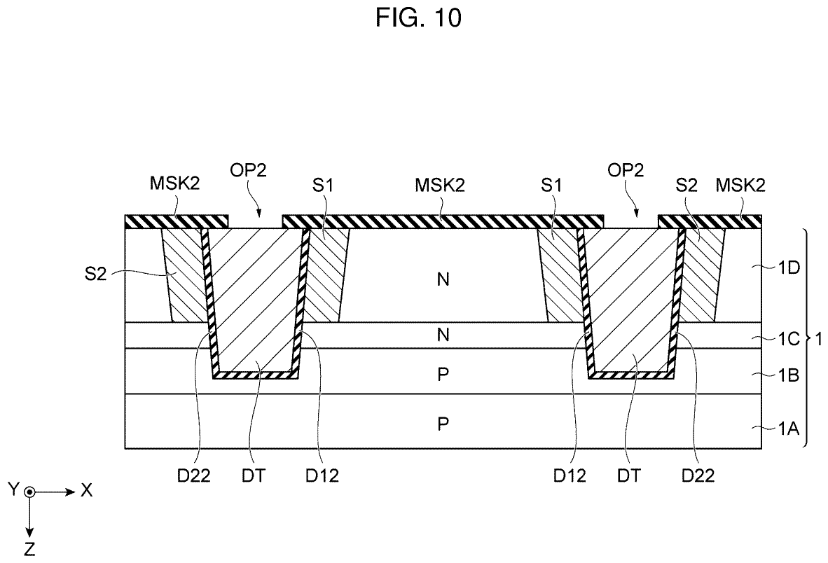

FIG. 10 is a diagram showing a vertical cross-sectional structure of a semiconductor device for explaining the manufacturing method of the semiconductor device.

Next, a second mask layer MSK2 is formed on the surface of the substrate 1. The second mask layer MSK2 is formed by, first, applying a resist to the surface of the epitaxial semiconductor layer 1D, performing exposure after setting a ring-shaped non-hardened area in a plan view, and then developing the resist. This removes the resist from the non-hardened area, resulting in the second mask layer MSK2 where, in a plan view, a ring-shaped second opening OP2 is patterned. The second openings OP2 are located in corresponding positions to the surfaces of the conductive material DT. The opening width of the second opening OP2 is smaller than the width of the upper opening of the trenches having the conductive material DT therein.

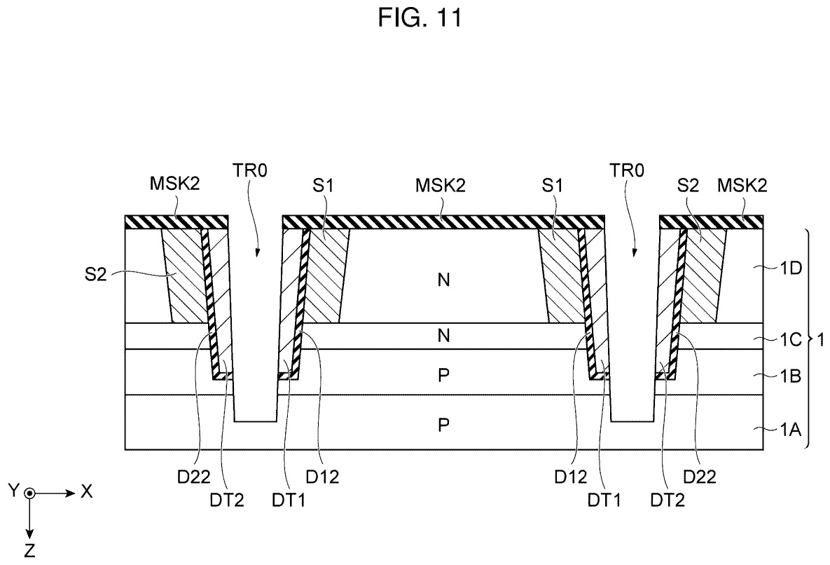

FIG. 11 is a diagram showing a vertical cross-sectional structure of a semiconductor device for explaining the manufacturing method of the semiconductor device.

Next, through the second opening OP2 (see FIG. 10) of the second mask layer MSK2, etching is performed on the substrate 1 to form the main trench TR0. This etching is performed from the surface of the epitaxial semiconductor layer 1D to reach into the semiconductor substrate 1A through the embedded semiconductor layer 1C and the base epitaxial semiconductor layer 1B. Because of the high aspect ratio of the main trench TR0, anisotropic etching may be used. Examples of the anisotropic etching (dry etching) method include RIE. Examples of the etching gas include gases containing fluorocarbons and halogens such as SF₆, but are not limited to these.

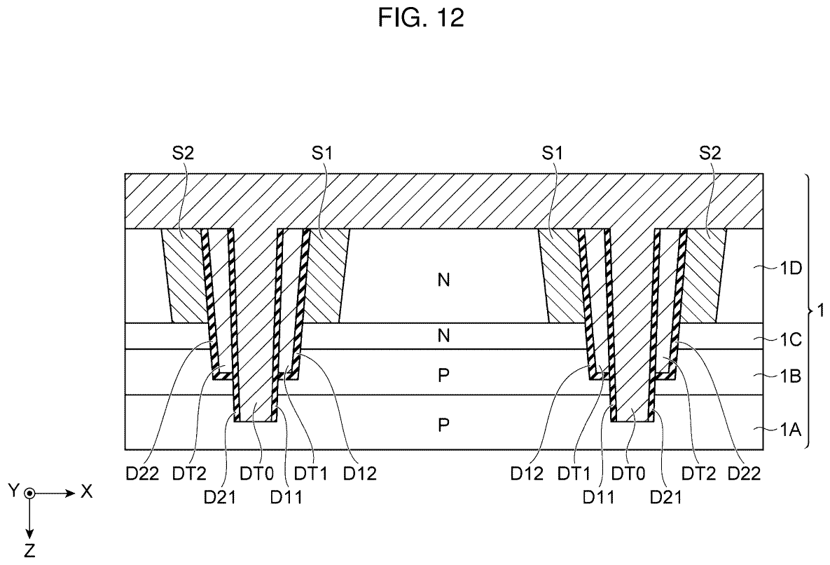

FIG. 12 is a diagram showing a vertical cross-sectional structure of a semiconductor device for explaining the manufacturing method of the semiconductor device.

Next, an insulating film is formed on the surface of the substrate 1, creating the first inner dielectric layer D11 and the first outer dielectric layer D21 made of this insulating layer in the main trench. If the insulating film is an oxide film (SiO₂), this oxide film may be formed by performing thermal oxidation on silicon, the CVD method, or sputtering. Examples of the material used in the CVD method include TEOS. After forming the insulating film on the surface of the substrate 1, the insulating film may be removed from the substate surface area except for the main trench inner surfaces through CMP and the like. The insulating film may be left instead of being removed. The material of the dielectric layers may be other materials than SiO₂.

After forming the first inner dielectric layer D11 and the first outer dielectric layer D21, a conductive material DT is deposited to fill up the main trench to form the conductive region DT0 inside the main trench. The conductive region DT0 is also deposited on the surface of the epitaxial semiconductor layer 1D. The conductive material is a polysilicon added with P-type impurity. Examples of the deposition method include sputtering and the CVD method using Si contained gas such as Silane.

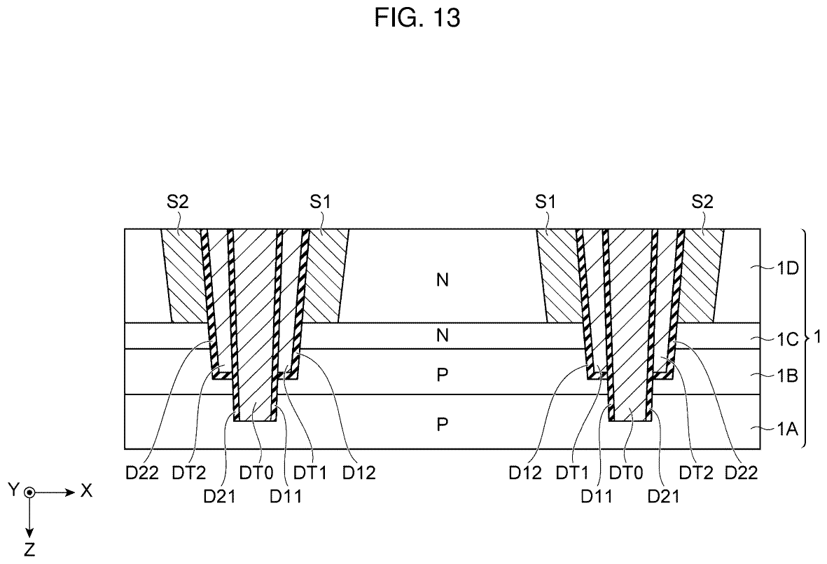

FIG. 13 is a diagram showing a vertical cross-sectional structure of a semiconductor device for explaining the manufacturing method of the semiconductor device.

Next, in the conductive material that constitutes the main conductive region DT0, parts thereof that are located on the surface of the substrate 1 is removed by CMP or the like. This exposes the top part of the second inner dielectric layer D12, the top part of the first outer dielectric layer D21, the top part of the first inner dielectric layer D11, the top part of the second outer dielectric layer D22, the top part of the first sinker region S1, and the top part of the second sinker region S2.

Lastly, as illustrated in FIG. 4A, an insulating region 18 is formed on the surface of the epitaxial semiconductor layer 1D. The insulating region 18 has a pattern with openings for the regions where various electrodes (main electrode E0, first electrode E11, second electrode E21, first sinker electrode E12, second sinker electrode E22) are to be formed. Examples of the method of forming the insulating region 18 include performing thermal oxidation on the exposed surface of the epitaxial semiconductor layer 1D, or etching the exposed surface and embedding silicon dioxide by the CVD method thereafter. On the surface of the first sinker region S1, the first sinker region contact region 12 is formed, and on the surface of the second sinker region S2, the second sinker region contact region 22 is formed. The contact regions may be formed by adding the same impurity as that of the sinker regions.

The trench structure described above functions as the deep trench isolation (DTI) structure by having the device 50 on the inside thereof. After forming this isolation structure, the device 50 such as a transistor may be formed in the region surrounded by the isolation structure.

FIG. 14 is a diagram showing a vertical cross-sectional structure of one exemplar device.

An FET, which is an active element that constitutes the device 50, is made of silicon (Si), and includes a N-type well region 51, a P-type well region 52, a source region SR, a drain region DR, a gate insulating film GX, and a gate electrode G1. Each well region is formed in the P-type semiconductor well region 14. The N-type well region 51 is made of an N-type semiconductor, and the P-type well region 52 is made of a P-type semiconductor. The source region SR and the drain region DR are made of an N-type semiconductor. The gate insulating film GX is made of SiO₂. The gate electrode G1 may be formed of polysilicon, and may include a metal such as copper (Cu) or aluminum (Al), an alloy including one or a plurality of types of metal, or a metal-silicon compound (silicide). The FET may include the second transistor Q2 that has a symmetric structure to the transistor structure constituted of those elements. The FET may be DMOS-FET. Also, a P-type contact region may be formed in a position adjacent to the source region SR.

Next, the material and impurity concentration of each semiconductor region described above will be explained.

The semiconductor material that constitutes the semiconductor chip 100 described above is silicon (Si). Alternatively, the semiconductor material that constitutes the semiconductor chip 100 may be a compound semiconductor. The compound semiconductor may be a III-V compound semiconductor, an IV-IV compound semiconductor, and an alloy semiconductor using these semiconductors. For the III-V compound semiconductor, Ga semiconductors such as GaAs or GaN may be used. For the IV-IV compound semiconductor, Si semiconductors such as SiC or SiGe may be used.

More specifically, the material of the semiconductor substrate 1A is silicon (Si). The material of the semiconductor substrate 1A may alternatively be a compound semiconductor such as silicon carbide (SiC) or gallium nitride (GaN), for example. The conductivity type of the semiconductor substrate 1A is P-type (first conductivity type), and the impurity concentration (C_{1A}) may be set to 1×10¹⁴ cm⁻³ to 5×10¹⁸ cm⁻³, for example. The thickness of the semiconductor substrate 1A is 250 μm to 800 μm, for example.

The material of the base epitaxial semiconductor layer 1B may be the same as the semiconductor substrate 1A. The conductivity type of the base epitaxial semiconductor layer 1B is P-type (first conductivity type). The impurity concentration (C_{1B}) of the base epitaxial semiconductor layer 1B may be set to 1×10¹³ cm⁻³ to 5×10¹⁶ cm⁻³, for example.

The material of the embedded semiconductor layer 1C may be the same as the semiconductor substrate 1A. The conductivity type of the embedded semiconductor layer 1C is N-type (second conductivity type), and the impurity concentration (C_{1C}) may be set to 1×10¹⁷ cm⁻³ to 1×10¹⁹ cm⁻³, for example. The thickness of the embedded semiconductor layer 1C may be 1 μm to 5 μm, for example.

The material of the epitaxial semiconductor layer 1D may be the same as the semiconductor substrate 1A. The conductivity type of the epitaxial semiconductor layer 1D is N-type (second conductivity type), and the impurity concentration (C_{1D}) may be set to 5×10¹⁴ cm⁻³ (sic) to 1×10¹⁷ cm⁻³, for example. The thickness of the epitaxial semiconductor layer 1D may be 3 μm to 20 μm, for example. The impurity concentrations of this example fulfills the relationship of C_{1D}<C_{1A}<C_{1C}. The conductivity type of the epitaxial semiconductor layer 1D may be P-type depending of the purposes, i.e., reducing the drain capacity of the n-channel DMOS transistor or the like.

The impurity concentration (C_{S1}) of the first sinker region S1 and the impurity concentration (C_{S2}) of the second sinker region S2 fulfill the relationship of (1×10¹⁵ cm⁻³≤C_{S1}≤1×10¹⁹ cm⁻³, 1×10¹⁵ cm⁻³≤C_{S2}≤1×10¹⁹ cm⁻³).

The impurity concentration of the epitaxial semiconductor layer 1D may be smaller than C_{S1} or C_{S2}.

The material of the N-well region 51 may be the same as the semiconductor substrate 1A. The conductivity type of the N-type well region 51 is N-type (second conductivity type), and the impurity concentration (C_{S1}) may be set to 1×10¹⁶ cm⁻³ to 1×10¹⁸ cm⁻³, for example. The thickness of the N-type well region 51 may be 0.5 μm to 4 μm, for example.

The material of the P-type well region 52 may be the same as the semiconductor substrate 1A. The conductivity type of the P-type well region 52 is P-type (first conductivity type), and the impurity concentration (C_{S2}) may be set to 1×10¹⁶ cm⁻³ to 1×10¹⁸ cm⁻³, for example. The thickness of the P-type well region 52 may be 0.5 μm to 4 μm, for example.

The material of the P-type semiconductor well region 14 may be the same as the semiconductor material of the semiconductor substrate 1A. The conductivity type of the P-type semiconductor well region 14 is P-type (first conductivity type), and the impurity concentration (C14) may be set to 1×10¹⁵ cm⁻³ to 1×10¹⁷ cm⁻³, for example, lower than the impurity concentration of the P-type well region 52. The thickness of the P-type semiconductor well region 14 may be 1 μm to 10 μm, for example.

The material of the source region SR and the drain region DR may be the same as the semiconductor substrate 1A. The conductivity type of the source region SR and the drain region DR is N-type (second conductivity type), and the impurity concentration (C_{SR}, C_{DR}) of each region may be set to 1×10¹⁹ cm⁻³ to 5×10²¹ cm⁻³, for example. The thickness of the source region SR and the drain region DR may be 0.2 μm to 1 μm, for example, but a configuration where the thickness of each region is made even smaller, or a configuration where the thickness of each region is made even greater may be employed.

The main conductive region DT0, the first conductive region DT1, and the second conductive region DT2 may be added with a high-concentration impurity. A high-concentration impurity may also be added to an area of the semiconductor substrate 1A located below the main conductive region DT0. The impurity concentration of each conductive region may be set to 1×10¹⁸ cm⁻³ to 1×10²² cm⁻³, for example. Other materials than polysilicon such as tungsten or copper may also be used for the material of those conductive regions.

(Additional Notes) As described above, various embodiments in this disclosure may be specified as follows.

[A1] A semiconductor device that has a base epitaxial semiconductor layer 1B, an embedded semiconductor layer 1C, and an epitaxial semiconductor layer 1D layered in this order on a semiconductor substrate 1A, including in a plan view: a main trench TR0; a first trench TR1 formed on a first side of the main trench TR0; a second trench TR2 formed on a second side of the main trench TR0; a first sinker region S1 formed on the first side of the first trench TR1; a second sinker region S2 formed on the second side of the second trench TR2; a main conductive region DT0 embedded in the main trench TR0; a first conductive region DT1 embedded in the first trench TR1; a second conductive region DT2 embedded in the second trench TR2; a first first-side dielectric layer (first inner dielectric layer D11) formed between the main conductive region DT0 and the first conductive region DT1; a second first-side dielectric layer (second inner dielectric layer D12) formed between the first conductive region DT1 and the first sinker region S1; a first second-side dielectric layer (first outer dielectric layer D21) formed between the main conductive region DT0 and the second conductive region DT2; and a second second-side dielectric layer (second outer dielectric layer D22) formed between the second conductive region DT2 and the second sinker region S2, wherein the main trench TR0 extends from the surface of the epitaxial semiconductor layer 1D through the base epitaxial semiconductor layer 1B, and the main conductive region DT0 is electrically connected to the semiconductor substrate A1, wherein the first trench TR1 and the second trench TR2 extend from the surface of the epitaxial semiconductor layer 1D to reach the base epitaxial semiconductor layer 1B, and the first conductive region DT1 and the second conductive region DT2 are electrically insulated from the base epitaxial semiconductor layer 1B.

[A2] The semiconductor device according to [A1] includes: a main electrode E0 electrically connected to the main conductive region DT0; a first electrode E11 electrically connected to the first conductive region DT1; a second electrode E21 electrically connected to the second conductive region DT2; a first sinker electrode E12 electrically connected to the first sinker region S1; and a second sinker electrode E22 electrically connected to the second sinker region S2.

[A3] The semiconductor device according to [A1], wherein a conductivity type of the semiconductor substrate 1A is a first conductivity type, wherein a conductivity type of the base epitaxial semiconductor layer 1B is the first conductivity type, wherein a conductivity type of the embedded semiconductor layer 1C is a second conductivity type, and wherein a conductivity type of the epitaxial semiconductor layer 1D is the second conductivity type.

[A4] The semiconductor device according to [A3], wherein a conductivity type of the first sinker region S1 is the first conductivity type, and a conductivity type of the second sinker region S2 is the first conductivity type.

The semiconductor device according to [A4], wherein the impurity concentration C_{S1} of the first sinker region S1 and the impurity concentration C_{S2} of the second sinker region S2 fulfill the relationship of 1×10¹⁵ cm⁻³≤C_{S1}≤1×10¹⁹ cm⁻³, 1×10¹⁵ cm⁻³≤C_{S2}≤1×10¹⁹ cm⁻³.

[A6] The semiconductor device according to [A5], further including a device 50 that is formed in the epitaxial semiconductor layer 1D, wherein in a plan view, the main trench TR0 is ring-shaped and surrounds the device 50, wherein the first side is an inner side and the second side is an outer side, wherein the device 50 includes an field-effect transistor formed in a semiconductor well region 14 of the first conductivity type, and wherein a shortest distance DX between the semiconductor well region 14 and the first sinker region S1 fulfills a relationship of 2 μm≤DX≤10 μm.

[A7] The semiconductor device according to [A1], further including a device 50 that is formed in the epitaxial semiconductor layer 1D, wherein in a plan view, the main trench TR0 is ring-shaped and surrounds the device 50, and wherein the first side is an inner side and the second side is an outer side.

[A8] The semiconductor device according to [A7], wherein, in a plan view, the first trench TR1 surrounds the device 50.

[A9] The semiconductor device according to [A8], wherein, in a plan view, the second trench TR2 surrounds the main trench TR0.

[A10] The semiconductor device according to [any one of A1 to A9], wherein the main conductive region DT0, the first conductive region DT1, and the first first-side dielectric layer between the main conductive region DT0 and the first conductive region DT1 constitutes a first first-side capacitor (first inner capacitor C11), wherein the main conductive region DT1, the first sinker region S1, and the second first-side dielectric layer between the first conductive region DT1 and the first sinker region S1 constitutes a second first-side capacitor (second inner capacitor C12), wherein the main conductive region DT0, the second conductive region DT2, and the first second-side dielectric layer between the main conductive region DT0 and the second conductive region DT2 constitutes a first second-side capacitor (first outer capacitor C21), wherein the second conductive region DT2, the second sinker region S2, and the second second-side dielectric layer between the second conductive region DT2 and the second sinker region S2 constitutes a second second-side capacitor (second outer dielectric layer D22), and wherein the second first-side capacitor (second inner capacitor C12), the first first-side capacitor (first inner capacitor C11), the first second-side capacitor (first outer capacitor C21), and the second second-side capacitor (second outer capacitor C22) are electrically connected to each other in series.

Various illustrative embodiments have been discussed above, but the present disclosure is not limited to those illustrative embodiments, and may be abridged, replaced or modified in various manners. Also, multiple elements from different embodiments may be combined to create another embodiment. It is understood from the descriptions above that the various embodiments of this disclosure are illustrative, and various modifications may be made without departing from the scope and purpose of the present disclosure. Thus, the various embodiments disclosed in the present specification are not intended to limit the present disclosure, and the true scope and purpose thereof are represented by the appended claims.

What is claimed is:

1. A semiconductor device that has a base epitaxial semiconductor layer, an embedded semiconductor layer, and an epitaxial semiconductor layer layered in this order on a semiconductor substrate, comprising in a plan view:
a main trench;
a first trench formed on a first side of the main trench;
a second trench formed on a second side of the main trench;
a first sinker region formed on a first side of the first trench;
a second sinker region formed on a second side of the second trench;
a main conductive region embedded in the main trench;
a first conductive region embedded in the first trench;
a second conductive region embedded in the second trench;
a first first-side dielectric layer formed between the main conductive region and the first conductive region;
a second first-side dielectric layer formed between the first conductive region and the first sinker region;
a first second-side dielectric layer formed between the main conductive region and the second conductive region; and
a second second-side dielectric layer formed between the second conductive region and the second sinker region,
wherein the main trench extends from a surface of the epitaxial semiconductor layer through the base epitaxial semiconductor layer, and the main conductive region is electrically connected to the semiconductor substrate, and
wherein the first trench and the second trench extend from the surface of the epitaxial semiconductor layer to reach the base epitaxial semiconductor layer, and the first conductive region and the second conductive region are electrically connected to the base epitaxial semiconductor layer.

2. The semiconductor device according to claim 1, further comprising:
a main electrode electrically connected to the main conductive region;
a first electrode electrically connected to the first conductive region;
a second electrode electrically connected to the second conductive region;
a first sinker electrode electrically connected to the first sinker region; and
a second sinker electrode electrically connected to the second sinker region.

3. The semiconductor device according to claim 1, wherein a conductivity type of the semiconductor substrate is a first conductivity type,
wherein a conductivity type of the base epitaxial semiconductor layer is the first conductivity type,
wherein a conductivity type of the embedded semiconductor layer is a second conductivity type, and
wherein a conductivity type of the epitaxial semiconductor layer is the second conductivity type.

4. The semiconductor device according to claim 3, wherein a conductivity type of the first sinker region is the first conductivity type, and
wherein a conductivity type of the second sinker region is the first conductivity type.

5. The semiconductor device according to claim 4, wherein an impurity concentration CS1 of the first sinker region and an impurity concentration CS2 of the second sinker region S2 fulfill the relationship:
1×10¹⁵ cm⁻³≤1×10¹⁵ cm⁻³≤CS1≤1×10¹⁹ cm⁻³,
1×10¹⁵ cm⁻³≤CS2≤1×10¹⁹ cm⁻³.

6. The semiconductor device according to claim 5, further comprising a device that is formed in the epitaxial semiconductor layer,
wherein in a plan view, the main trench is ring-shaped and surrounds the device,
wherein the first side of the main trench is an inner side and the second side of the main trench is an outer side,
wherein the device includes a field-effect transistor formed in a semiconductor well region of the first conductivity type, and
wherein a shortest distance DX between the semiconductor well region and the first sinker region fulfills a relationship of 2 μm≤DX≤10 μm.

7. The semiconductor device according to claim 1, further comprising a device that is formed in the epitaxial semiconductor layer,
wherein, in a plan view, the main trench is ring-shaped and surrounds the device, and
wherein the first side of the main trench is an inner side and the second side of the main trench is an outer side.

8. The semiconductor device according to claim 7, wherein, in a plan view, the first trench surrounds the device.

9. The semiconductor device according to claim 8, wherein, in a plan view, the second trench surrounds the main trench.

10. The semiconductor device according to claim 1, wherein the main conductive region, the first conductive region, and the first first-side dielectric layer between the main conductive region and the first conductive region constitute a first first-side capacitor,
wherein the first conductive region, the first sinker region, and the second first-side dielectric layer between the first conductive region and the first sinker region constitute a second first-side capacitor,
wherein the main conductive region, the second conductive region, and the first second-side dielectric layer between the main conductive region and the second conductive region constitute a first second-side capacitor,
wherein the second conductive region, the second sinker region, and the second second-side dielectric layer between the second conductive region and the second sinker region constitute a second second-side capacitor, and
wherein the second first-side capacitor, the first first-side capacitor, the first second-side capacitor, and the second second-side capacitor are electrically connected to each other in series.
